(19) United States
(12) Patent Application Publication
(10) Pub. No.: US 2025/0140528 A1
(43) Pub. Date: May 1, 2025

(54) YTTRIA COATING FOR PLASMA PROCESSING CHAMBER COMPONENTS

(71) Applicant: Lam Research Corporation, Fremont, CA (US)

(72) Inventors: Jeremiah Michael DEDERICK, Livermore, CA (US); Satish SRINIVASAN, Newark, CA (US); Lin XU, Fremont, CA (US); John DAUGHERTY, Fremont, CA (US)

(21) Appl. No.: 18/867,773

(22) PCT Filed: May 17, 2023
(86) PCT No.: PCT/US2023/022492

§ 371 Date: Nov. 20, 2024

Related U.S. Application Data
(60) Provisional application No. 63/346,043, filed on May 26, 2022.

(51) Int. Cl. H01J 37/32; C23C 16/44

(52) U.S. Cl. CPC H01J 37/32495; C23C 16/4404; H01J 2237/334

(57) ABSTRACT

A component of a plasma processing chamber is provided. A yttria coating is formed on a surface of a component body, wherein the yttria coating is deposited by aerosol deposition and is annealed, wherein the yttria coating is at least 95% pure yttria by weight.

### CROSS-REFERENCE TO RELATED APPLICATION

This application claims the benefit of priority of U.S. Application No. 63/346,043, filed May 26, 2022, which is incorporated herein by reference for all purposes.

### BACKGROUND

The present disclosure generally relates to the manufacturing of semiconductor devices. More specifically, the disclosure relates to plasma chamber components used in manufacturing semiconductor devices.

During semiconductor wafer processing, plasma processing chambers are used to process semiconductor devices. Plasma processing chambers are subjected to plasmas, which may degrade components in the plasma processing chambers. Components of the plasma processing chamber that are degraded by plasma are a source of contaminants. Ceramic alumina (aluminum oxide (Al₂O₃)) is a common material used for components in plasma processing chambers, as alumina is somewhat plasma etch-resistant. However, alumina is not sufficiently plasma etch resistant.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a component of a plasma processing chamber is provided. A yttria coating is formed on a surface of a component body, wherein the yttria coating is deposited by aerosol deposition and is annealed, wherein the yttria coating is at least 95% pure yttria by weight.

In another manifestation, a component body is adapted for use in a plasma processing chamber. An aerosol deposition coating of a yttria powder is deposited on the component body, wherein the aerosol deposition coating is at least 95% by weight yttria. The aerosol deposition coating is annealed.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-C are schematic views of a component processed according to an embodiment.

FIG. 3 is a schematic view of a plasma processing chamber that may be used in an embodiment.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Aerosol deposition (AD) coating technologies remain a frequently deployed method to create a “plasma or etch-resistant” coating on chamber parts. However, as manufacturers move to future technology nodes and apply ever more stringent criteria on particles; particle-generation persists as the primary failure mode for these types of barrier coatings. Smooth versions of AD coated parts tend to have weak areas found at termination zones, the edges of the coating. For some parts texturing is required, the texturing often has a higher propensity to shed particles because the coating is less dense (texturing is difficult to achieve on a fully densified coating).

According to some embodiments described herein, a component of a plasma processing chamber is provided with a coating that is more etch-resistant. The coating is deposited using yttrium oxide (Y₂O₃) (also known as yttria) powder.

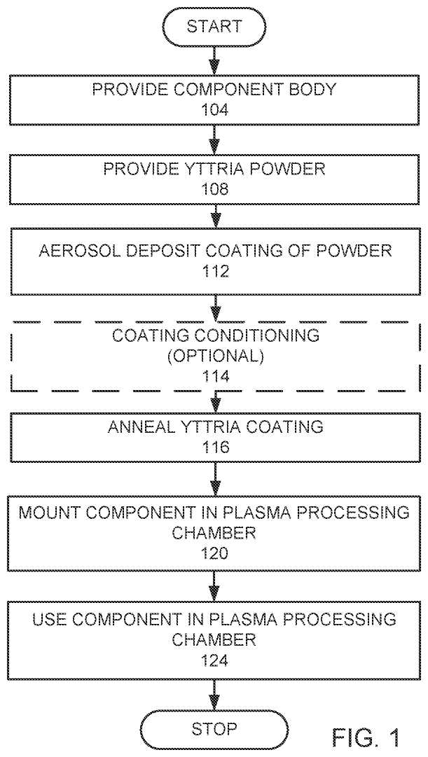

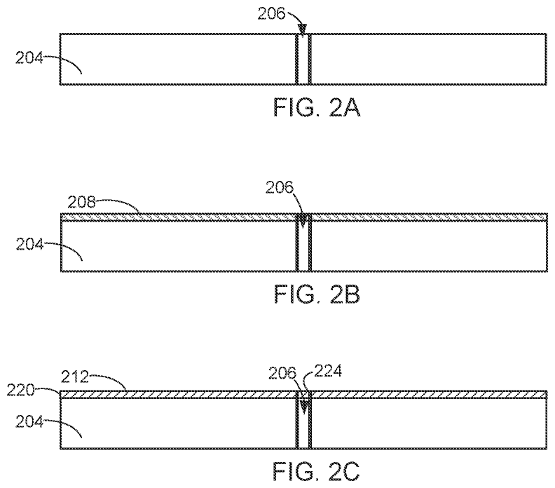

To facilitate understanding, FIG. 1 is a high level flow chart of a process used in an embodiment. A component body is provided (step 104). FIG. 2A is a schematic cross-sectional view of a component body 204 that is used in an embodiment. In some embodiments, the component body 204 comprises a ceramic material. In some embodiments, the component body 204 is made of ceramic alumina. In some embodiments, the ceramic alumina component body 204 is a dielectric power window. In some embodiments, a borehole 206 passes through the center of a power window to provide a gas injector.

A yttria powder is provided (step 108). In this example, the yttria powder is at least 95% pure by weight. In some embodiments, the average grain size of the yttria powder is in the range of 40 nm to 50 nm.

An aerosol deposition coating of the yttrium oxide powder is then deposited on the surface of the component body 204 (step 112). Aerosol deposition is achieved by passing a carrier gas through a fluidized bed of solid yttria powder. Driven by a pressure difference, the yttria powder particles are accelerated through a nozzle, forming an aerosol jet at its outlet. The aerosol is then directed at the surface of the component body 204, where the aerosol jet impacts the surface with high velocity. The powder mixture particles break up into solid nanosized fragments, forming a coating. Optimization of carrier gas species, gas consumption, standoff distance, and scan speed provides high-quality coatings. As noted above, aerosol deposition can take place at room temperature. FIG. 2B is a schematic cross-sectional view of the component body 204 after the aerosol deposition of the AD coating 208 of the yttria powder has been deposited.

After the AD coating 208 is deposited (step 112), optional coating conditioning processes may be provided to the AD coating 208 (step 114). For example, in some embodiments, the AD coating 208 may be cleaned and polished. In some embodiments, the cleaning may comprise a 3000 grit abrasive scrub of the entire window surface in order to remove polish slurry and loose grains or debris. A scrubbing may then be applied followed by a blasting of solid CO₂, in order to remove any remaining loose features and/or scrub residue. A precision wet clean using deionized water may then follow. The window may then be baked.

Next, the AD coating 208 is annealed (step 116). In this embodiment, the AD coating is heated to a temperature in the range of 650° C. to 890° C. In some embodiments, the AD coating is heated to a temperature in the range of 700° C. to 850° C. The annealing temperature is kept below 900° C. in order to prevent some of the yttria from combining with aluminum oxide to form a yttrium aluminum oxide compound. The formation of yttrium aluminum oxide compounds would increase porosity resulting in a decrease in erosion resistance at the termination zones. By keeping the annealing temperature below 900° C., the coating remains at least 95% pure yttria by weight. In some embodiments, the annealing process provides the maximum temperature for a time in the range of 4 to 12 hours. In addition, to prevent the component body 204 from cracking the temperature is ramped up and ramped down at a speed of no more than 30° C. per hour. In some embodiments, the annealing is done in atmosphere, where oxygen might be available and present. FIG. 2C is a cross-section image of the AD coating after AD coating is annealed to form an annealed coating 212. A measurement of the grain size using a transmission electron microscope has found that the annealing process has increased the average grain size from the range of 40 nm to 50 nm to the range of 70 nm to 100 nm. In some embodiments, the annealing causes the grain size to increase by between 1.5 to 2.5 times. In some embodiments, a transmission electron microscope electron backscatter (TEM-EBS) process may be used to measure average grain size. Also, X-ray diffraction is a method for determining the mean size of single-crystal nanoparticles or crystallites in nanocrystalline bulk materials. The Scherrer equation relates the size of crystallites in a solid to the broadening of a peak (or peaks) in a diffraction pattern. The Scherrer equation is Dₕₖₗ=Kλ/(Bₕₖₗ cos0), where Dₕₖₗ=crystallite size in the direction perpendicular to the lattice planes, hkl=Miller indices of the planes being analyzed, K is a numerical factor frequently referred to as the crystallite-shape factor, λ is the wavelength of the X-rays, Bₕₖₗ is the width (full-width at half-maximum) of the X-ray diffraction peak in radians and θ is the Bragg angle.

In some embodiments the annealed coating 212; is at least 95% (by weight) pure yttria, has a porosity of less than 1% by volume, and has an average thickness of between 5 μm to 20 μm. In some embodiments, the annealed coating 212 is at least 99% pure yttria by weight.

After the AD coating 208 has been annealed (step 116), optional conditioning of the annealed coating 212 may be provided (step 114). For example, the annealed coating 212 may be scrubbed and then blasted, and then subjected to a final clean. In some embodiments, the blasting of the annealed coating 212 may be performed by blasting the annealed coating 212 with frozen carbon dioxide. When the annealing process causes grain growth, the annealing may cause some grains to protrude out, so that they are weakly connected or grains may otherwise be forced out as the surrounding grains grow, causing an exfoliation. The cleaning processes may be used to remove any loose particles on the annealed coating 212 that may be caused by the annealing process in order to reduce contaminants. Some embodiments may use cleaning processes like the cleaning processes provided after applying the AD coating.

Post annealing of parts with an AD coating 208, provides the possibility to “tune” internal grain structure and porosity to achieve specific material morphologies/properties. A post-anneal offers a path to tailor grain size in the AD yttria coating 208, by promoting grain growth. As a consequence of grain growth, coating densification improves; along with the additional effect of grain fusing (a reduction of inter-grain porosity). At surface level, grain coarsening (propagated by annealing) can alter the surface roughness and micro-porosity. Furthermore, annealing can reduce internal stresses in the AD yttria coating 208, thereby mitigating fractures/delamination events.

Since the annealing process increases density, reduces porosity, and increases the grain size—the overall effect may lead to a decreased rate at which the coating might be etched by hydrochloric acid (HCl). In some embodiments, an AD coating 208 before annealing subjected to a 5 mass-% concentration HCl roughens from a range of 10 nm to 20 nm roughness to a range of 60 nm to 100 nm roughness in about 3 minutes. In some embodiments, an annealed coating 212 subjected to a 5 mass-% concentration HCl stays in the roughness range of 10 nm to 20 nm roughness after up to 30 minutes of exposure to HCl. The HCl test shows that the annealing makes the coating more erosion resistant

The component body 204 is mounted in a plasma processing chamber (step 120). In the illustrated example, the component body 204 is mounted in the plasma processing chamber as a dielectric inductive power window. The plasma processing chamber is used to process a substrate (step 124), where a plasma is created within the chamber to process a substrate, such as etching the substrate, and the annealed coating 212 is exposed to the plasma. The annealed coating 212 provides increased etch resistance to protect the component body 204.

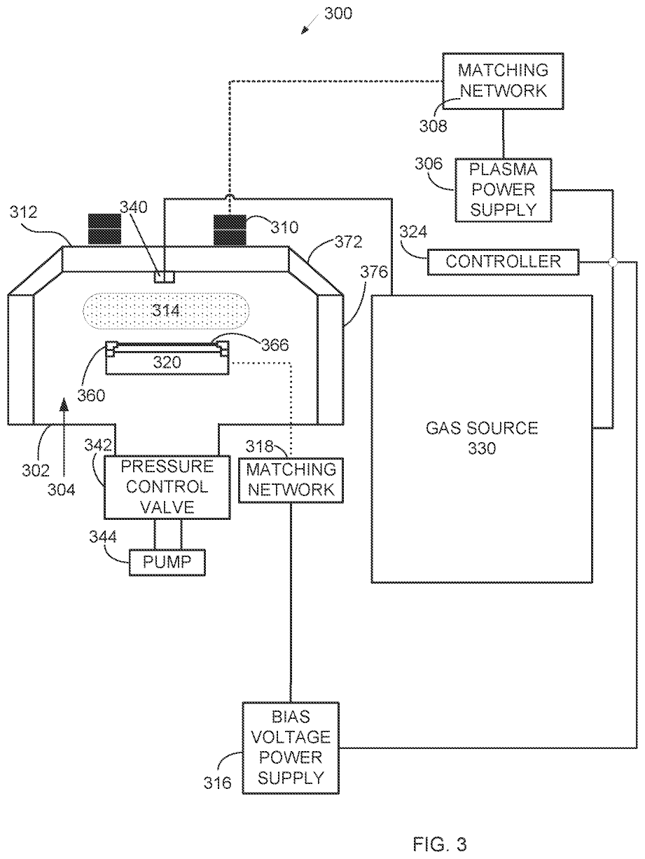

FIG. 3 schematically illustrates an example of a plasma processing chamber system 300 that may be used in an embodiment. The plasma processing chamber system 300 includes a plasma reactor 302 having a plasma processing confinement chamber 304 therein. A plasma power supply 306, tuned by a matching network 308, supplies power to a transformer coupled plasma (TCP) coil 310 located near a dielectric inductive power window 312 to create a plasma 314 in the plasma processing confinement chamber 304 by providing an inductively coupled power. A pinnacle 372 extends from a chamber wall 376 of the plasma processing confinement chamber 304 to the dielectric inductive power window 312 forming a pinnacle ring. The pinnacle 372 is angled with respect to the chamber wall 376 and the dielectric inductive power window 312, such that the interior angle between the pinnacle 372 and the chamber wall 376 and the interior angle between the pinnacle 372 and the dielectric inductive power window 312 are each greater than 90° and less than 180°. The pinnacle 372 provides an angled ring near the top of the plasma processing confinement chamber 304, as shown. The TCP coil (upper power source) 310 may be configured to produce a uniform diffusion profile within the plasma processing confinement chamber 304. For example, the TCP coil 310 may be configured to generate a toroidal power distribution in the plasma 314. The dielectric inductive power window 312 is provided to separate the TCP coil 310 from the plasma processing confinement chamber 304 while allowing energy to pass from the TCP coil 310 to the plasma processing confinement chamber 304. A wafer bias voltage power supply 316 tuned by a matching network 318 provides power to an electrode 320 to set the bias voltage on the substrate 366. The substrate 366 is supported by the electrode 320. A controller 324 controls the plasma power supply 306 and the wafer bias voltage power supply 316.

The plasma power supply 306 and the wafer bias voltage power supply 316 may be configured to operate at specific radio frequencies such as for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve desired process performance. For example, in one embodiment, the plasma power supply 306 may supply the power in a range of 50 to 5000 Watts, and the wafer bias voltage power supply 316 may supply a bias voltage in a range of 20 to 2000 volts (V). In addition, the TCP coil 310 and/or the electrode 320 may be comprised of two or more sub-coils or sub-electrodes. The sub-coils or sub-electrodes may be powered by a single power supply or powered by multiple power supplies.

As shown in FIG. 3, the plasma processing chamber system 300 further includes a gas source/gas supply mechanism 330. The gas source 330 is in fluid connection with plasma processing confinement chamber 304 through a gas inlet, such as a gas injector 340. The gas injector 340 may be located in any advantageous location in the plasma processing confinement chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 304. More preferably, the gas injector is mounted to the dielectric inductive power window 312. The gas injector may be mounted on, mounted in, or form part of the power window. The process gases and by-products are removed from the plasma process confinement chamber 304 via a pressure control valve 342 and a pump 344. The pressure control valve 342 and pump 344 also serve to maintain a particular pressure within the plasma processing confinement chamber 304. The pressure control valve 342 can maintain a pressure of less than 1 torr during processing. An edge ring 360 is placed around the substrate 366. The gas source/gas supply mechanism 330 is controlled by the controller 324. A Kiyo by Lam Research Corp. of Fremont, CA, may be used to practice an embodiment.

In various embodiments, the component may be other parts of a plasma processing chamber, such as confinement rings, edge rings, Corvus rings, electrostatic chucks (ESC), ground rings, chamber liners, door liners, inner electrodes/showerheads, outer electrodes, other components through which radio frequency (RF) energy can pass, crosses, sleeves, pins, nozzles, injectors, forks, arms, etc. Other components of other types of plasma processing chambers may be used. For example, plasma exclusion rings on a bevel etch chamber may be coated in an embodiment. In another example, the plasma processing chamber may be a dielectric processing chamber or conductor processing chamber. In some embodiments, the component body 204 is formed of a ceramic material. In other embodiments, the component body 204 is formed of a silicon (Si) material. In some embodiments, one or more, but not all, surfaces are coated.

In some embodiments, the component is an inductive power window 312 with a gas injector 340 that passes through the borehole 206 of the inductive power window 312. In such an embodiment, the annealed coating 212 has termination zones 220, shown in FIG. 2C, on the outer edge of the inductive power window 312, shown in FIG. 3, and termination zones 224, shown in FIG. 2C, on the inner edge of borehole 206 used to provide the gas injector 340, shown in FIG. 3. An unannealed coating would have more porosity at termination zones than at other parts of the coatings. The higher porosity results in more erosion and more contaminants caused by erosion. Since the gas injector 340 is above the center of the wafer, the termination zones near the gas injector would cause more contaminant particles near the center of the wafer. Such an increase of contaminant particles has been found near the center of the wafer. The annealing of the coating reduces erosion and contaminant particles near the center of the wafer. Since some embodiments improve erosion resistance at terminal points where the coating is more prone to erosion, some embodiments provide erosion resistance that is more uniform across the coating including the termination zones. Since the annealing causes grain growth, the annealing also reduces voids that cause pitting, because crystal growth cinches off pits. In some embodiments, the coating at the termination zones has a density of at least 95% by volume. In some embodiments, the coating at termination zones has a density of at least 99% by volume. In some embodiments, the coating at termination zones has a porosity of less than 1% by volume. The above mentioned HCl test helps to indicate such a low porosity.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A component of a plasma processing chamber, comprising:
a component body; and
a yttria coating on a surface of the component body, wherein the yttria coating is deposited by aerosol deposition and is annealed, wherein the yttria coating is at least 95% pure yttria by weight.

2. The component, as recited in claim 1, wherein the yttria coating has an average yttria grain size in a range of 70 to 100 nm.

3. The component, as recited in claim 1, wherein the yttria coating is annealed at a maximum temperature in a range of 650° C. to 900° C.

4. The component, as recited in claim 1, wherein the component body is formed of a ceramic material.

5. The component, as recited in claim 1, wherein the component body forms a power window.

6. The component, as recited in claim 1, wherein the yttria coating has a porosity of less than 1% by volume.

7. The component, as recited in claim 1, wherein the component body forms at least one of a power window.

8. The component, as recited in claim 1, wherein the yttria coating at termination zones has a porosity of less than 1% by volume.

9. A method, comprising:
providing a component body adapted for use in a plasma processing chamber;
depositing an aerosol deposition coating of a yttria powder on the component body, wherein the aerosol deposition coating is at least 95% by weight yttria; and
annealing the aerosol deposition coating.

10. The method, as recited in claim 9, wherein the annealing the aerosol deposition coating, comprises annealing the yttria coating at a maximum temperature in a range of 650° C. to 900° C.

11. The method, as recited in claim 9, wherein the aerosol deposition coating has an average yttria grain size in a range of 70 to 100 nm.

12. The method, as recited in claim 9, wherein the providing the component body comprises forming a ceramic component body.

13. The method, as recited in claim 9, wherein the providing the component body comprises forming a power window.

14. The method, as recited in claim 9, wherein the annealing the aerosol deposition coating is provided in the presence of oxygen.
